(19) United States
(12) Patent Application Publication
(10) Pub. No.: US 2025/0105230 A1
(43) Pub. Date: Mar. 27, 2025

(54) SEMICONDUCTOR PACKAGE AND MANUFACTURING METHOD THEREOF

(71) Applicant: INDUSTRIAL TECHNOLOGY RESEARCH INSTITUTE, Hsinchu (TW)

(72) Inventors: Chih-Wei PENG, Zhudong Township (TW); Chih-Cheng HSIAO, Xinpu Township (TW); Ching-Feng YU, Yuanli Township (TW)

(73) Assignee: INDUSTRIAL TECHNOLOGY RESEARCH INSTITUTE, Hsinchu (TW)

(21) Appl. No.: 18/752,267

(22) Filed: Jun. 24, 2024

(30) Foreign Application Priority Data
Sep. 26, 2023 (TW) 112136811

(51) Int. Cl. H01L 25/16; H01L 23/00; H01L 23/13; H01L 23/31; H01L 23/538; H01L 27/144

(52) U.S. Cl. CPC H01L 25/167; H01L 23/13; H01L 23/3107; H01L 23/5383; H01L 24/16; H01L 24/32; H01L 24/73; H01L 2224/16225; H01L 2224/32225; H01L 2224/73204; H10F 39/10

(57) ABSTRACT

A semiconductor package includes a carrier plate, a photonic integrated circuit chip, an electronic integrated circuit chip and an interposer substrate. The carrier plate has a notch and a first surface and a second surfaces opposite to the first surface, and the notch extends from the first surface toward the second surface. The photonic integrated circuit chip is disposed within the notch. The electronic integrated circuit chip is disposed on the first surface of the carrier plate. The photonic integrated circuit chip and the electronic integrated circuit chip are disposed on the carrier through the interposer substrate.

This application claims the benefit of Taiwan application Serial No. 112136811, filed Sep. 26, 2023, the disclosure of which is incorporated by reference herein in its entirety.

### TECHNICAL FIELD

The disclosure relates in general to a semiconductor package and a manufacturing method thereof.

### BACKGROUND

Heterogenous integration is the integration of multiple electronic components of different properties into single system-in-package (SiP) through multi-dimensional space design, for example, 2.5D and 3D. In the existing manufacturing process of the packaging structure with photonic integrated circuit chip, the photonic integrated circuit chip participates in multiple manufacturing steps of the packaging structure, such as heating, alkali cleaning, etc. However, the optical waveguide layer of the photonic integrated circuit chip is easily damaged by these process steps. Therefore, proposing a semiconductor package and its manufacturing method that may improve the aforementioned conventional problems is one of the goals of those in this technical field.

### SUMMARY

The present disclosure provides a semiconductor package and a manufacturing method thereof.

According to one embodiment, a semiconductor package is provided. The semiconductor package includes a carrier plate, a photonic integrated circuit chip, an electronic Integrated circuit chip and an interposer substrate. The carrier plate has a notch, a first surface and a second surface opposite to the first surface, wherein the notch extends from the first surface toward the second surface. The photonic integrated circuit chip is disposed within the notch. The electronic integrated circuit chip is disposed on the first surface of the carrier plate. The photonic integrated circuit chip and the electronic integrated circuit chip are disposed on the carrier plate through the interposer substrate.

According to another embodiment, a manufacturing method for a semiconductor package is provided. The manufacturing method includes the following steps: providing a carrier plate, wherein the carrier plate has a notch, a first surface and a second surface opposite to the first surface, and the notch extends from the first surface toward the second surface; and disposing a photonic integrated circuit chip and an electronic integrated circuit chip on the carrier through an interposer substrate, wherein the photonic integrated circuit chip is disposed within the notch, and the electronic integrated circuit chip is disposed on the first surface of the carrier plate.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1A illustrates a schematic diagram of a top view of a semiconductor package according to an embodiment of the present invention;

FIG. 1B illustrates a schematic diagram of a bottom view of the semiconductor package in FIG. 1A;

FIG. 2A illustrates a schematic diagram of a cross-sectional view of the semiconductor package in FIG. 1A along a direction 2A-2A′;

FIG. 2B illustrates a schematic diagram of a cross-sectional view of the semiconductor package in FIG. 1A along a direction 2B-2B′;

FIG. 3A illustrates a schematic diagram of a top view of the semiconductor package according to another embodiment of the present invention;

FIG. 3B illustrates a schematic diagram of a bottom view of the semiconductor package in FIG. 3A;

FIG. 4A illustrates a schematic diagram of a cross-sectional view of the semiconductor package in FIG. 3A along a direction 4A-4A′;

FIG. 4B illustrates a cross-sectional view of the semiconductor package in FIG. 3A along a direction 4B-4B′;

FIG. 5A illustrates a schematic diagram a top view of a semiconductor package according to another embodiment of the present invention;

FIG. 5B illustrates a schematic diagram of a bottom view of the semiconductor package in FIG. 5A;

FIGS. 6A to 6F illustrate schematic diagrams of manufacturing processes of the semiconductor package in FIG. 1A;

FIGS. 7A to 7F illustrate schematic diagrams of manufacturing processes of the semiconductor package in FIG. 3A; and

FIGS. 8A to 8C illustrate the manufacturing process diagram of the semiconductor package in FIG. 5A.

### DETAILED DESCRIPTION

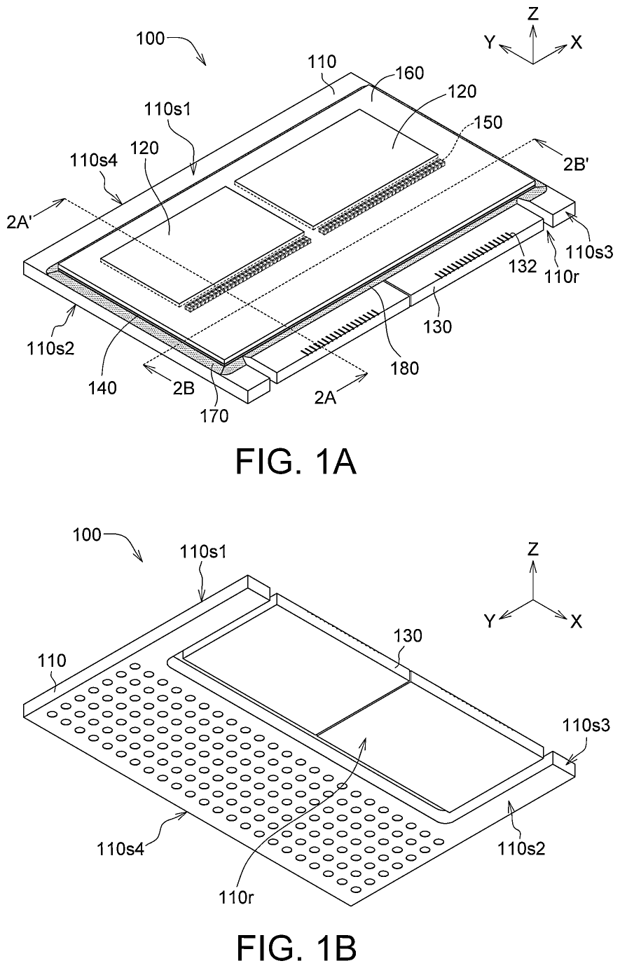

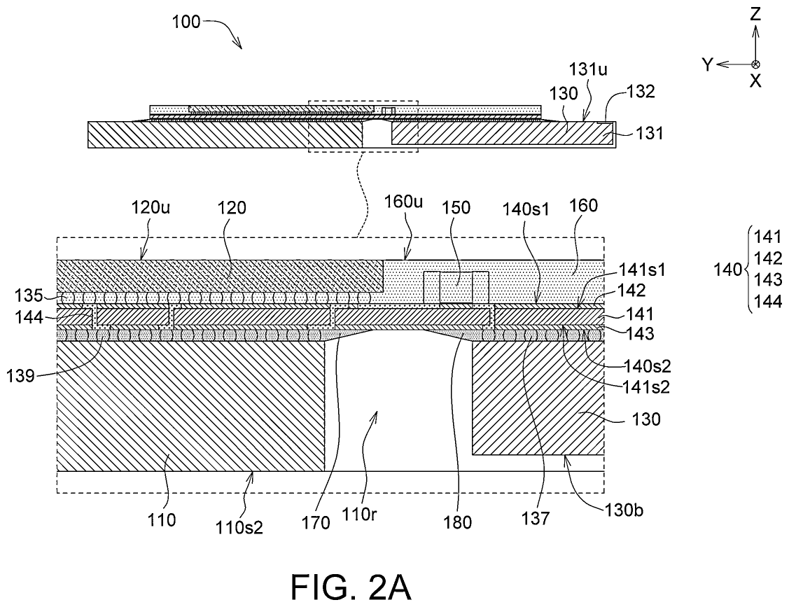

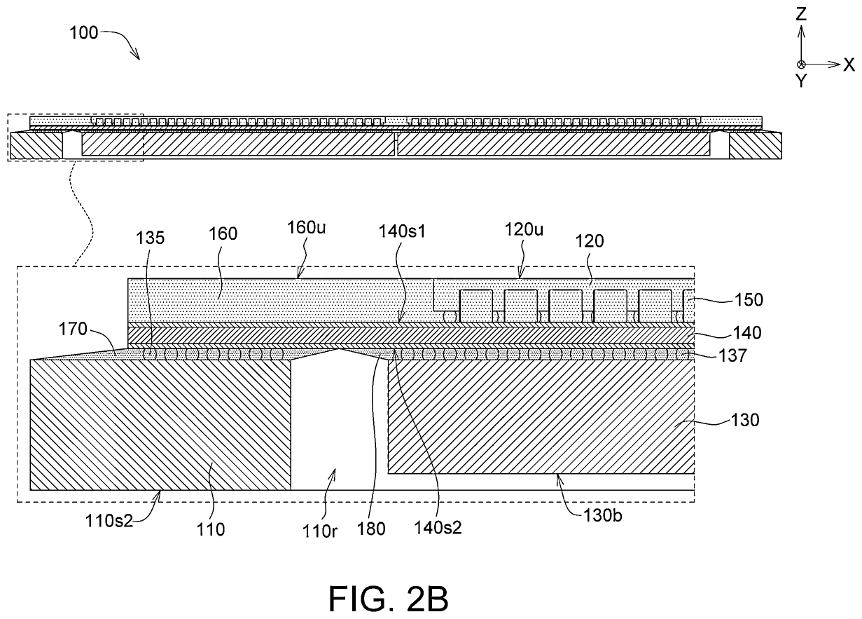

Referring to FIGS. 1A to 2B, FIG. 1A illustrates a schematic diagram of a top view of a semiconductor package 100 according to an embodiment of the present invention, FIG. 1B illustrates a schematic diagram of a bottom view of the semiconductor package 100 in FIG. 1A, FIG. 2A illustrates a schematic diagram of a cross-sectional view of the semiconductor package 100 in FIG. 1A along a direction 2A-2A′, and FIG. 2B illustrates a schematic diagram of a cross-sectional view of the semiconductor package 100 in FIG. 1A along a direction 2B-2B′.

As illustrated in FIGS. 1A to 1B, the semiconductor package 100 includes a carrier plate 110, at least one first electronic integrated circuit (EIC) chip 120, at least one photonic integrated circuit (PIC) chip 130, at least one interposer substrate 140, at least one contact 135, at least one contact 137, at least one contact 139, at least one passive component 150, a package body 160, a first underfill 170 and a second underfill 180.

As illustrated in FIGS. 1A to 1B, the carrier plate 110 has a notch 110r, a first surface 110s1 and a second surface 110s2 opposite to the first surface 110s1. The notch 110r extends to the second surface 110s2 from the first surface 110s1. The first electronic integrated circuit chip 120 is disposed on the first surface 110s1 of the carrier plate 110. The photonic integrated circuit chip 130 is disposed within the notch 110r. Due to the design of the notch in the carrier plate 110, the photonic integrated circuit chip 130 is allowed to be assembled to the notch 110r of the carrier plate 110 after being individually manufactured. Due to the photonic integrated circuit chip 130 being manufactured individually, the photonic integrated circuit chip 130 may be prevented from participating in the manufacturing process of the first electronic integrated circuit chip 120, thereby reducing pollution on components (for example, optical waveguide components) of the photonic integrated circuit chip 130 or the probability of damage (the optical waveguide may remain intact to facilitate optical coupling). In addition, due to the photonic integrated circuit chip 130 being manufactured individually, it may meet the diverse manufacturing requirements in high-mix low-volume and/or shorten the development time of packaging modules, and other advantages.

As illustrated in FIGS. 1A to 1B, the carrier plate 110 is, for example, a U-shaped plate. Furthermore, the notch 110r is a through hole extending to the second surface 110s2 from the first surface 110s1. The carrier plate 110 further has a third surface 110s3 and a fourth surface 110s4 opposite to the third surface 110s3. The third surface 110s3 and the fourth surface 110s4 extend between the first surface 110s1 and the second surface 110s2. The notch 110r further extends from the third surface 110s3 toward the fourth surface 110s4, but does not extend to the fourth surface 110s4.

The carrier plate 110 may be made by, for example, a printed circuit board (PCB) process, an integrated circuit carrier plate process, or a ceramic substrate process. Although not illustrated, the carrier plate 110 may include at least one trace, at least one pad, and at least one conductive via to electrically connect with components disposed on the carrier plate 110 and/or electrically connect the components disposed on the carrier plate 110 with an external component, such as an external circuit board.

The first electronic integrated circuit chip 120 is, for example, a chip with Cu pillar bumps, a chip with solder bump, or a Fan-out chip scale package or a CoWoS (Chip on Wafer on Substrate), etc. In an embodiment, the first electronic integrated circuit chip 120 may be a digital signal processor (DSP) or an application specific integrated circuit (ASIC).

As illustrated in FIGS. 1A to 1B, the photonic integrated circuit chip 130 may be entirely disposed within the notch 110r. In another embodiment, a portion of the photonic integrated circuit chip 130 is disposed inside the notch 110r, but the other portion of the photonic integrated circuit chip 130 may be located outside the notch 110r.

As illustrated in FIGS. 2A and 2B, the photonic integrated circuit chip 130 has a lower surface 130b, and the lower surface 130b of the photonic integrated circuit chip 130 is recessed relative to the second surface 110s2. As a result, the photonic integrated circuit chip 130 may be prevented from protruding relative to the second surface 110s2 and interfering with components located below it, such as a circuit board (not illustrated).

As illustrated in FIGS. 1A and 2A, the photonic integrated circuit chip 130 further includes a base 131 and at least one optical waveguide component 132. The substrate 131 is, for example, a silicon substrate, such as a silicon wafer. The optical waveguide component 132 is formed in the base 131. The optical waveguide component 132 is, for example, a silicon waveguide, and its material includes, for example, silicon, silicon nitride (SiN), etc. The optical waveguide component 132 is exposed from an upper surface 131u of the base 131 to receive external optical signal. In the present embodiment, since the photonic integrated circuit chip 130 does not participate in the manufacturing process of the first electronic integrated circuit chip 120, the carrier plate 110 and/or the interposer substrate 140, it may avoid being polluted or damaged by these manufacturing processes.

As illustrated in FIGS. 2A and 2B, the interposer substrate 140 has a fifth surface 140s1 and a sixth surface 140s2 opposite to the fifth surface 140s1. The first electronic integrated circuit chip 120 is disposed on the fifth surface 140s1 of the interposer substrate 140, and the photonic integrated circuit chip 130 is disposed on the sixth surface 140s2 of the interposer substrate 140. For example, the contact 135 is disposed between the first electronic integrated circuit chip 120 and the fifth surface 140s1 of the interposer substrate 140 to electrically connect the first electronic integrated circuit chip 120 with the interposer substrate 140. In an embodiment, the contacts 135 may be pre-formed on the first electronic integrated circuit chip 120 or the interposer substrate 140, and the first electronic integrated circuit chip 120 and the interposer substrate 140 are connected through the contacts 135. The contact 137 is disposed between the photonic integrated circuit chip 130 and the sixth surface 140s2 of the interposer substrate 140 to electrically connect the photonic integrated circuit chip 130 with the interposer substrate 140. In an embodiment, the contacts 137 may be pre-formed on the photonic integrated circuit chip 130 or the interposer substrate 140, and the photonic integrated circuit chip 130 and the interposer substrate 140 are connected through the contacts 137. In addition, the contact 139 is disposed between the carrier plate 110 and the sixth surface 140 s2 of the interposer substrate 140 to electrically connect the carrier plate 110 with the interposer substrate 140. In an embodiment, the contacts 139 may be pre-formed on the carrier plate 110 or the interposer substrate 140, and the carrier plate 110 and the interposer substrate 140 are connected through the contacts 139. The aforementioned contacts 135, 137, and 139 are, for example, conductive solder balls, conductive pillars, and/or conductive bumps.

As illustrated in FIGS. 2A and 2B, the interposer substrate 140 includes a base 141, a first RDL (RDL) 142, a second RDL 143 and at least one conductive via 144. The substrate 141 is, for example, a silicon substrate, such as a silicon wafer. The base 141 has a first base surface 141s1 and a second base surface 141s2 opposing to the first base surface 141s1. The first RDL 142 is formed on the first substrate surface 141s1 of the substrate 141, and the second RDL 143 is formed on the second substrate surface 141s2 of the substrate 141. The conductive via 144 is, for example, a through silicon via (TSV) which is formed on the base 141 and connects the first RDL 142 with the second RDL 143. Since the interposer substrate is a silicon-based substrate, an interval between two adjacent conductive vias 144 is in the level of millimeter or micron, and such design may provide high-density output/input contacts. Through the interposer substrate 140, at least two of the carrier plate 110, the first electronic integrated circuit chip 120, the photonic integrated circuit chip 130 and the passive component 150 may be electrically connected.

As illustrated in FIGS. 2A and 2B, each passive component 150 is, for example, a resistor, a capacitor or an inductor. In terms of capacitance, the passive component 150 is, for example, a multi-layer ceramic capacitor (MLCC). The passive component 150 is disposed on the interposer substrate 140. For example, the passive component 150 is disposed on and electrically connected to the first RDL 142 of the interposer substrate 140. The passive component 150 may be electrically connected to the first electronic integrated circuit chip 120 and/or the photonic integrated circuit chip 130 through the first RDL 142.

As illustrated in FIGS. 2A and 2B, the package body 160 is formed on the interposer substrate 140 and encapsulates the first electronic integrated circuit chip 120 and the passive component 150. The first electronic integrated circuit chip 120 has an upper surface 120u, wherein the upper surface 120u is exposed from the package body 160 for communicating with an external environment. As a result, the heat generated by the first electronic integrated circuit chip 120 may be quickly conducted to the external environment through the upper surface 120u.

The package body 160 is, for example, a molding compound. The package body 160 may include, for example, Novolac-based resin, epoxy-based resin, silicone-based resin or other appropriate coating agents. The package body 160 may also include appropriate fillers, such as powdered silicon dioxide. The package body 160 may be formed using several packaging technologies, such as compression molding, liquid encapsulation, injection molding or transfer molding.

As illustrated in FIGS. 2A and 2B, the package body 160 has an upper surface 160u. The upper surface 160u of the package body 160 is substantially flush with the upper surface 120u of the first electronic integrated circuit chip 120. In terms of manufacturing process, after the package body 160 is formed to cover the upper surface 120u of the first electronic integrated circuit chip 120, the package body 160 may be planarized to expose the upper surface 120u of the first electronic integrated circuit chip 120 by using technique, for example, grinding, or planarized until the planarized upper surface 160u of the package body 160 is substantially flush with the upper surface 120u of the first electronic integrated circuit chip 120. The aforementioned grinding technology is, for example, mechanical grinding or chemical polishing.

As illustrated in FIGS. 2A and 2B, the first underfill 170 is formed between the interposer substrate 140 and the carrier plate 110, and encapsulates the contacts 139 between the interposer substrate 140 and the carrier plate 110 to protect these contacts 139. The first underfill 170 also has the function of fixing the relative position between the interposer substrate 140 and the carrier plate 110. The second underfill 180 is formed between the interposer substrate 140 and the photonic integrated circuit chip 130, and encapsulates the contacts 137 between the interposer substrate 140 and the photonic integrated circuit chip 130 to protect these contacts 137. The second underfill 180 also has the function of fixing the relative position between the interposer substrate 140 and the photonic integrated circuit chip 130. In another embodiment, although not illustrated, the semiconductor package 100 further includes an adhesive that may be formed between the photonic integrated circuit chip 130 and the carrier plate 110 to fix the relative position between the photonic integrated circuit chip 130 and the carrier plate 110.

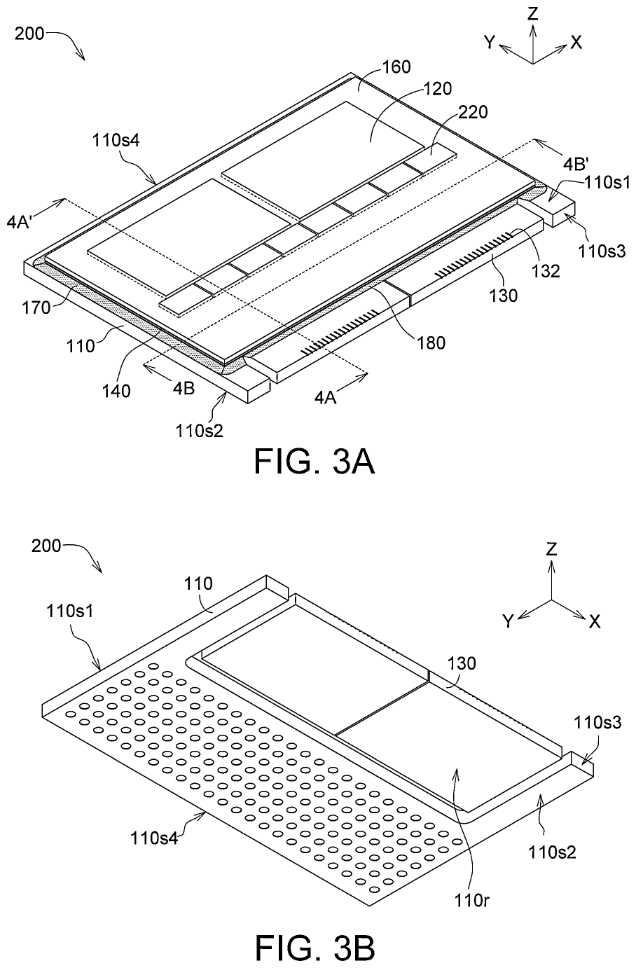

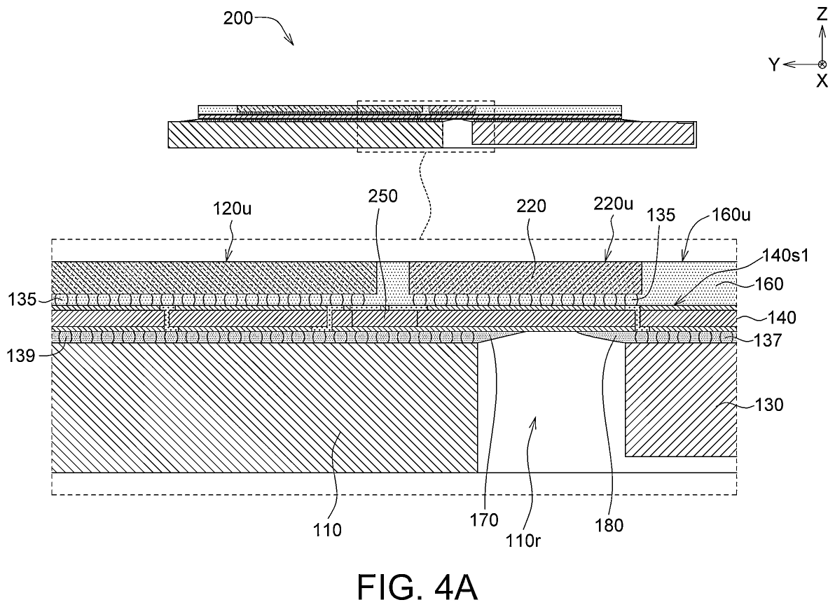

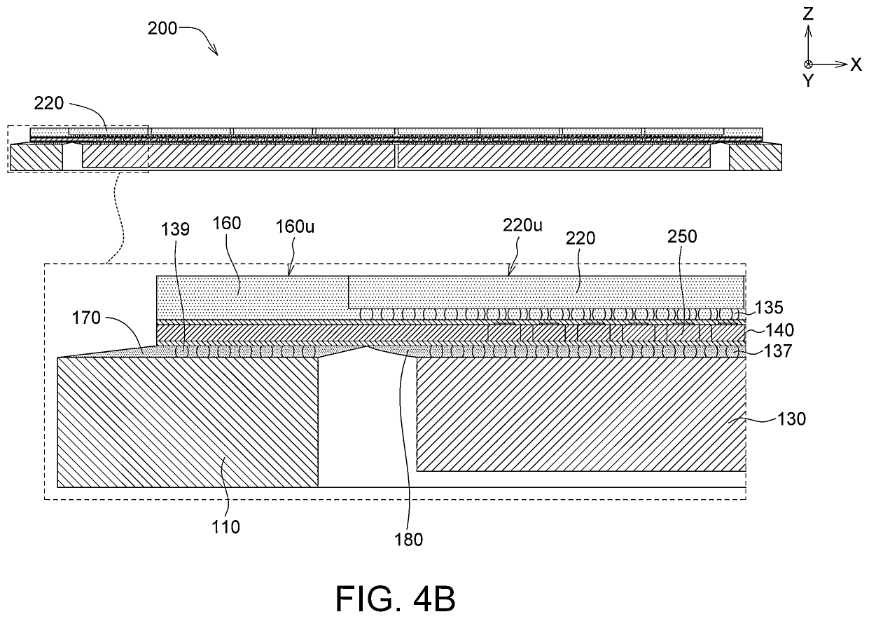

Referring to FIGS. 3A to 4B, FIG. 3A illustrates a schematic diagram of a top view of the semiconductor package 200 according to another embodiment of the present invention, FIG. 3B illustrates a schematic diagram of a bottom view of the semiconductor package 200 in FIG. 3A, FIG. 4A illustrates a schematic diagram of a cross-sectional view of the semiconductor package 200 in FIG. 3A along a direction 4A-4A′, and FIG. 4B illustrates a cross-sectional view of the semiconductor package 200 in FIG. 3A along a direction 4B-4B′.

As illustrated in FIGS. 3A to 3B, the semiconductor package 200 includes a carrier plate 110, at least one first electronic integrated circuit chip 120, at least one contact 135, at least one contact 137, at least one contact 139, and at least one second electronic integrated circuit chip 220, at least one photonic integrated circuit chip 130, the interposer substrate 140, at least one passive component 250, the package body 160, the first underfill 170 and the second underfill 180.

The semiconductor package 200 includes the features (structure, material, connection relationship, etc.) the same as or similar to that of the aforementioned semiconductor package 100, and one of the differences is that the semiconductor package 200 further includes the second electronic integrated circuit chip 220.

As illustrated in FIGS. 3A to 3B, the carrier plate 110 has a notch 110r, a first surface 110s1 and a second surface 110s2 opposite to the first surface 110s1. The notch 110r extends to the second surface 110s2 from the first surface 110s1. The first electronic integrated circuit chip 120 and the second electronic integrated circuit chip 220 are disposed on the first surface 110s1 of the carrier plate 110. The photonic integrated circuit chip 130 is disposed within the notch 110r. Due to the design of the notch in the carrier plate 110, the photonic integrated circuit chip 130 is allowed to be assembled to the notch 110r of the carrier plate 110 after being individually manufactured. Due to the photonic integrated circuit chip 130 being manufactured individually, the photonic integrated circuit chip 130 may be prevented from participating in the manufacturing process of the first electronic integrated circuit chip 120, thereby reducing pollution on components (for example, optical waveguide components) of the photonic integrated circuit chip 130 or the probability of damage (the optical waveguide may remain intact to facilitate optical coupling). In addition, due to the photonic integrated circuit chip 130 being manufactured individually, it may meet the diverse manufacturing requirements in high-mix low-volume and/or shorten the development time of packaging modules, and other advantages.

As illustrated in FIGS. 3A and 4A, the type and/or structure of the second electronic integrated circuit chip 220 is, for example, the same as or similar to that of the first electronic integrated circuit chip 120. In an embodiment, the difference between the second electronic integrated circuit chip 220 and the first electronic integrated circuit chip 120 is that the second electronic integrated circuit chip 220 may be a chip with single function such as a transimpedance amplifier (TIA) or a driver (Driver), which is configured to assist functions that the first electronic integrated circuit chip 120 may lack. The second electronic integrated circuit chip 220 has an upper surface 220u. The upper surface 220u of the second electronic integrated circuit chip 220 is substantially flush with the upper surface 160u of the package body 160. In terms of manufacturing process, after the package body 160 is formed to encapsulate the upper surface 220u of the second electronic integrated circuit chip 220 and the upper surface 120u of the first electronic integrated circuit chip 120, the package body 160 may be planarized to expose the upper surface 220u of the second electronic integrated circuit chip 220 and the upper surface 120u of the first electronic integrated circuit chip 120 by using technique, for example, grinding, or planarized until the planarized upper surface 160u of the package body 160 is substantially flush with the upper surface 220u of the second electronic integrated circuit chip 220 and the upper surface 120u of the first electronic integrated circuit chip 120.

As illustrated in FIG. 4A, at least one contact 135 is disposed between the second electronic integrated circuit chip 220 and the fifth surface 140s1 of the interposer substrate 140 to electrically connect the second electronic integrated circuit chip 220 with the interposer substrate 140. In an embodiment, the contacts 135 may be pre-formed on the second electronic integrated circuit chip 220 or the interposer substrate 140, and the second electronic integrated circuit chip 220 and the interposer substrate 140 are connected through the contacts 135.

As illustrated in FIGS. 4A and 4B, in the present embodiment, the passive component 250 is embedded in the interposer substrate 140 and may be electrically connect the first RDL 142 with the second RDL 143. The passive component 250 may be electrically connected to the first electronic integrated circuit chip 120 and/or the second electronic integrated circuit chip 220 through the first RDL 142 and/or the second RDL 143.

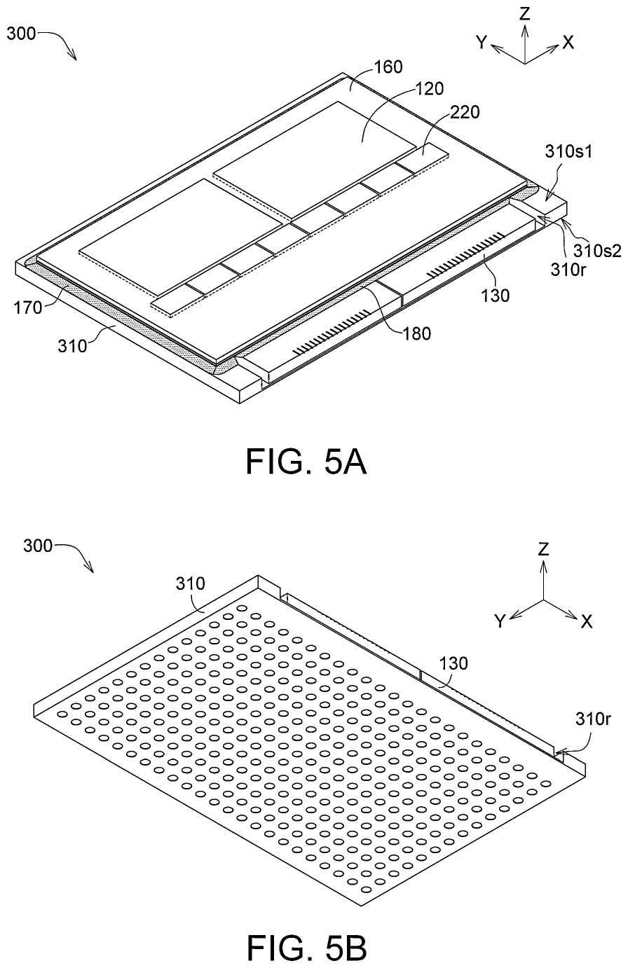

Referring to FIGS. 5A to 5B, FIG. 5A illustrates a schematic diagram a top view of a semiconductor package 300 according to another embodiment of the present invention, and FIG. 5B illustrates a schematic diagram of a bottom view of the semiconductor package 300 in FIG. 5A.

As illustrated in FIGS. 5A to 5B, the semiconductor package 300 includes a carrier plate 310, at least one first electronic integrated circuit chip 120, at least one second electronic integrated circuit chip 220, at least one photonic integrated circuit chip 130, the interposer substrate 140, at least one passive component 150 (not illustrated), the package body 160, the first underfill 170 and the second underfill 180.

The semiconductor package 300 includes features (structure, material, connection relationship, etc.) the same as or similar to that of the aforementioned semiconductor package 100, and one of the differences is that the structure of the carrier plate 310 of the semiconductor package 300 is different from that of the carrier plate 110 of the semiconductor package 200.

As illustrated in FIGS. 5A and 5B, the carrier plate 310 has a notch 310r, a first surface 310s1 and a second surfaces 310s1 opposite to the first surface 310s1. The notch 310r extends to the second surface 310s2 from the first surface 310s1. The first electronic integrated circuit chip 120 and the second electronic integrated circuit chip 220 are disposed on the first surface 310s1 of the carrier plate 310. The photonic integrated circuit chip 130 is disposed within the notch 310r. Due to the design of the notch in the carrier plate 310, the photonic integrated circuit chip 130 is allowed to be assembled to the notch 310r of the carrier plate 310 after being individually manufactured. Due to the photonic integrated circuit chip 130 being manufactured individually, the photonic integrated circuit chip 130 may be prevented from participating in the manufacturing process of the first electronic integrated circuit chip 120, thereby reducing pollution on components (for example, optical waveguide components) of the photonic integrated circuit chip 130 or the probability of damage (the optical waveguide may remain intact to facilitate optical coupling). In addition, due to the photonic integrated circuit chip 130 being manufactured individually, it may meet the diverse manufacturing requirements in high-mix low-volume and/or shorten the development time of packaging modules, and other advantages.

As illustrated in FIGS. 5A to 5B, the notch 310r extends to the second surface 110s2 from the first surface 110s1, but does not extend to the second surface 110s2. In other words, different from the aforementioned carrier plate 110, the notch 310r of the carrier plate 310 in the embodiment of the present invention is a groove that does not penetrate the carrier plate 310. The other features (material, structure and/or connection relationship, etc.) of the carrier plate 310 are the same as or similar to that of the aforementioned carrier plate 110 and it will not be repeated again here.

From the above, it may be seen that due to the use of the carrier plate with notch, a plurality of the circuits (or chips) with different sizes and functions may be integrated into one semiconductor package. Such design not only has high flexibility and high-density integration, but also takes into account the needs of chip heat dissipation, electrical optimization and optical coupling convenience.

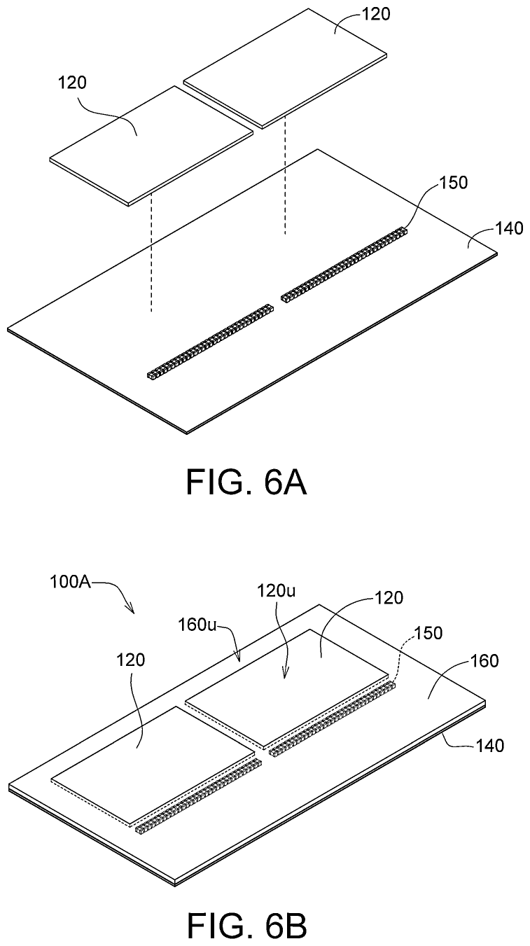

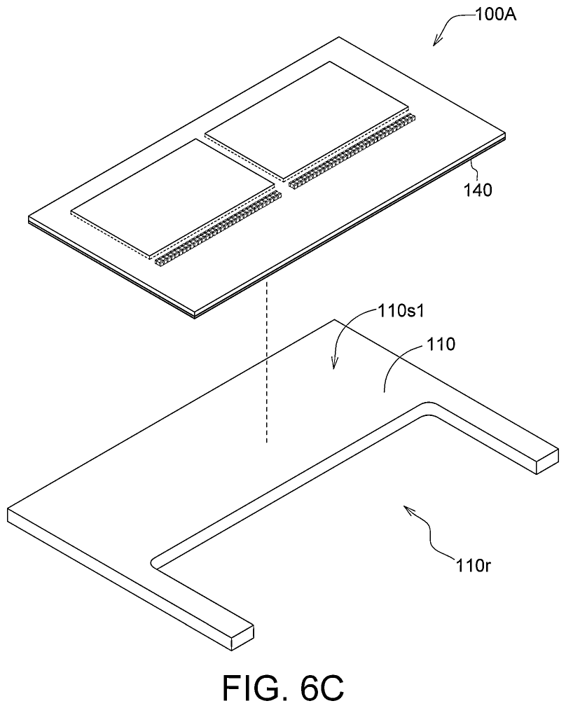

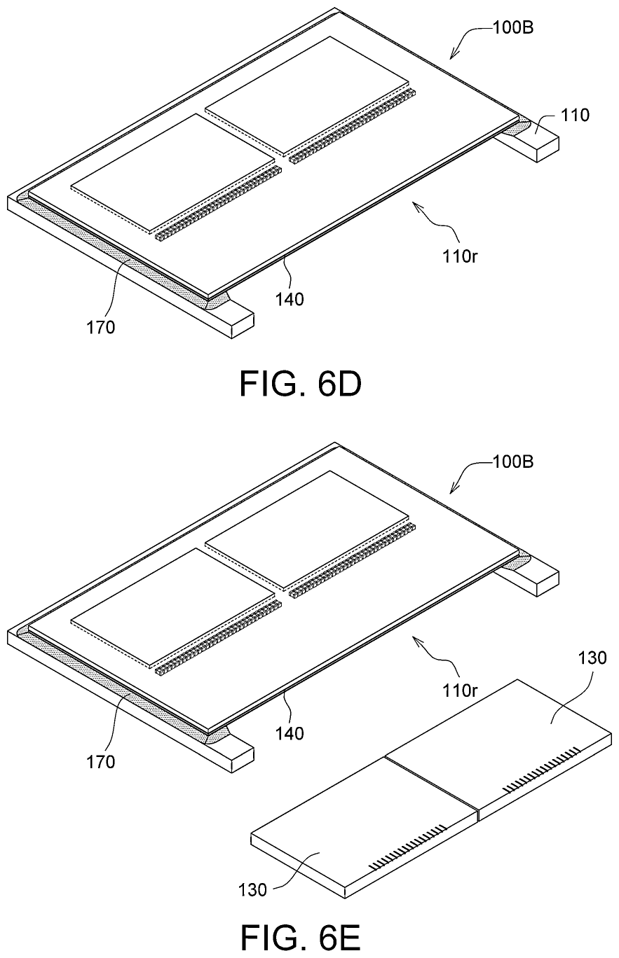

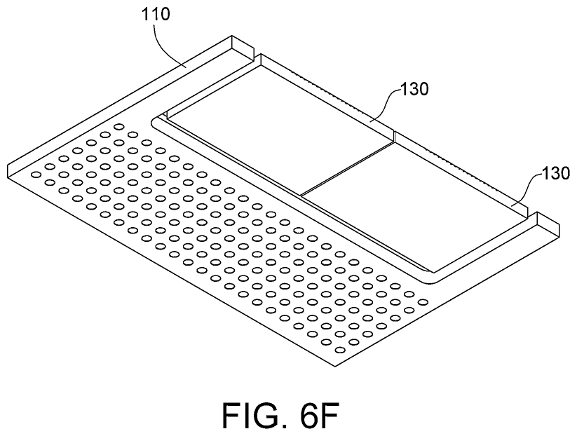

Referring to FIGS. 6A to 6F, FIGS. 6A to 6F illustrate the manufacturing process diagram of the semiconductor package 100 in FIG. 1A.

As illustrated in FIG. 6A, at least one first electronic integrated circuit chip 120 and at least one passive component 150 are disposed on the interposer substrate 140. Although not illustrated, the aforementioned contacts 135 (the contacts 135 are illustrated in FIG. 2A) may be pre-formed on the carrier plate 110 or the first electronic integrated circuit chip 120. The carrier plate 110 and the first electronic integrated circuit chip 120 are butted and electrically connected through the contacts 135.

As illustrated in FIG. 6B, the package body 160 may be formed on the interposer substrate 140 to encapsulate the first electronic integrated circuit chip 120 and the passive component 150 by using, for example, compression molding, liquid encapsulation, injection molding or transfer molding. Then, the package body 160 may be planarized to expose the upper surface 120u of the first electronic integrated circuit chip 120 by using, for example, grinding technology, or planarized until the upper surface 160u of the package body 160 is substantially flush with the upper surface 120u of the first electronic integrated circuit chip 120.

As illustrated in FIG. 6C, the structure 100A in FIG. 6B may be disposed on the first surface 110s1 of the carrier plate 110 by using, for example, flip-chip technology. The structure 100A is, for example, a multi-chip heterogeneous integrated module. In addition, although not illustrated, the aforementioned contacts 139 (the contacts 139 are illustrated in FIG. 2A) may be pre-formed on the carrier plate 110 or the interposer substrate 140. The carrier plate 110 and the interposer substrate 140 may be butted and electrically connected through the contacts 139.

As illustrated in FIG. 6D, the first underfill 170 may be formed between the interposer substrate 140 and the carrier plate 110 by using, for example, dispensing technology, and encapsulate the contacts 139 (the contacts 139 are illustrated in FIG. 2A) between the interposer substrate 140 and the carrier plate 110.

As illustrated in FIG. 6E, at least one photonic integrated circuit chip 130 is disposed on the notch 110r of the carrier plate 110 of the structure 100B in FIG. 6D by using, for example, flip-chip technology. The arranged structure is illustrated in FIG. 6F. In an embodiment, the structure 100B in FIG. 6E may be inverted so that the notch 110r faces upward, so that the photonic integrated circuit chip 130 is disposed downwardly in the notch 110r. In addition, although not illustrated, the aforementioned contacts 137 (the contacts 137 are illustrated in FIG. 2A) may be pre-formed on the interposer substrate 140 or the photonic integrated circuit chip 130. The interposer substrate 140 and the photonic integrated circuit chip 130 may be butted and electrically connected through the contacts 137.

Then, the second underfill 180 (illustrated in FIG. 2A) may be formed between the interposer substrate 140 in FIG. 6F and the photonic integrated circuit chip 130 by using, for example, dispensing technology, and encapsulate the contacts 137 (the contacts 137 are illustrated in FIG. 2A) between the interposer substrate 140 and the photonic integrated circuit chip 130.

Then, although not illustrated, in another embodiment, an adhesive may be formed between the photonic integrated circuit chip 130 in FIG. 6F and the carrier plate 110 for fixing the relative position between the photonic integrated circuit chip 130 and the carrier plate 110.

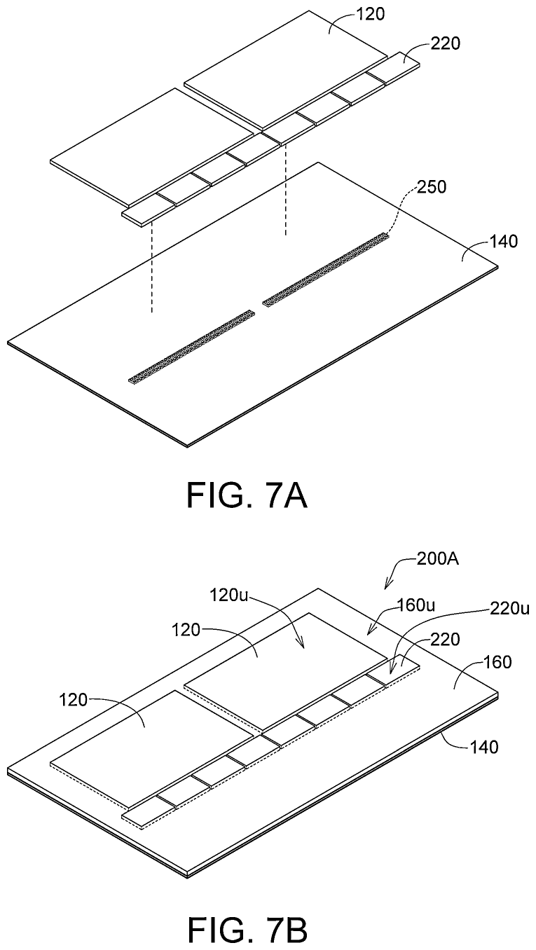

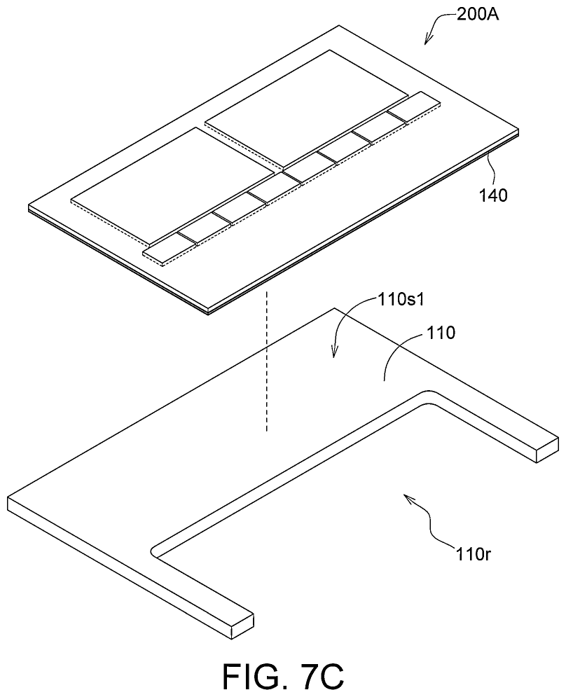

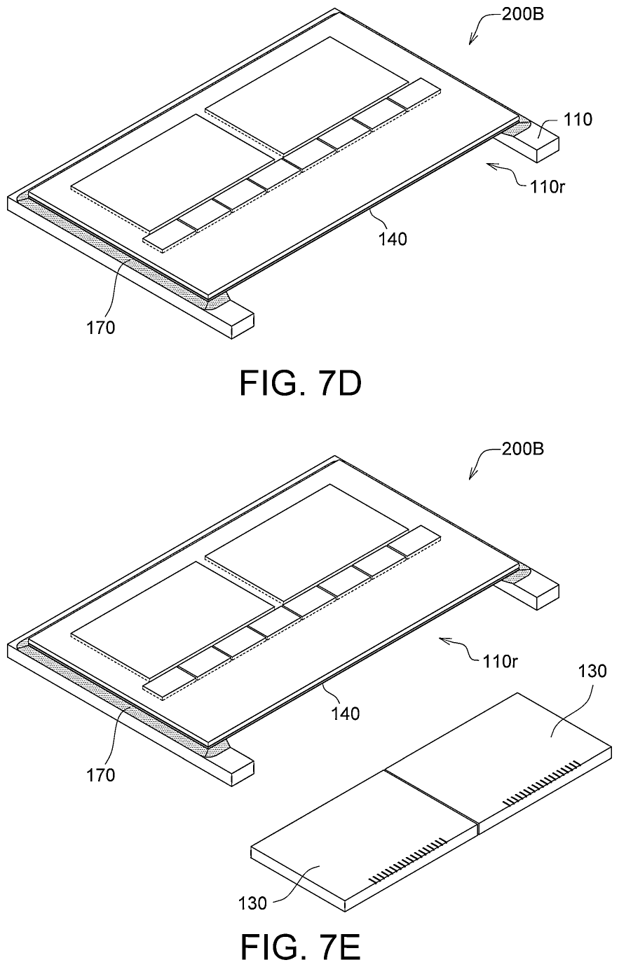

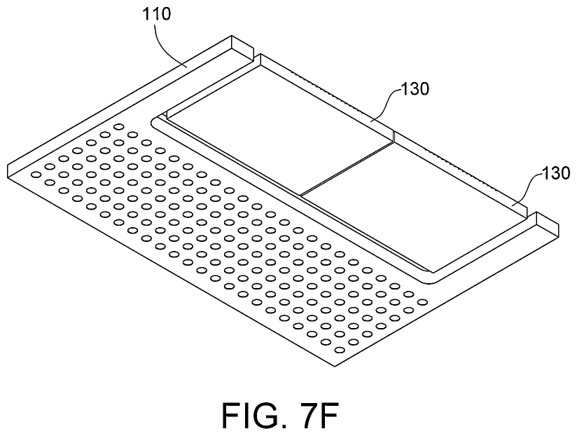

Referring to FIGS. 7A to 7F, FIGS. 7A to 7F illustrate schematic diagrams of manufacturing processes of the semiconductor package 200 in FIG. 3A.

As illustrated in FIG. 7A, at least one first electronic integrated circuit chip 120 and at least one second electronic integrated circuit chip 220 may be disposed on the interposer substrate 140, wherein at least one passive component 250 may be embedded in the interposer substrate 140. In addition, although not illustrated, the aforementioned contacts 135 may be pre-formed on the first electronic integrated circuit chip 120 or the interposer substrate 140, and the first electronic integrated circuit chip 120 and the interposer substrate 140 may be butted and electrically connected through the contacts 135. In addition, although not illustrated, the aforementioned contacts 135 may be pre-formed on the second electronic integrated circuit chip 220 or the interposer substrate 140, and the second electronic integrated circuit chip 220 and the interposer substrate 140 may be butted and electrically connected through the contacts 135. In addition, the aforementioned contacts 135 may be pre-formed on the first electronic integrated circuit chip 120 or the interposer substrate 140, and may be pre-formed on the second electronic integrated circuit chip 220 or the interposer substrate 140.

As illustrated in FIG. 7B, the package body 160 may be formed on the interposer substrate 140 and encapsulate the first electronic integrated circuit chip 120 and the second electronic integrated circuit chip 120 by using, for example, compression molding, liquid encapsulation, injection molding or transfer molding. Then, the package body 160 may be planarized to expose the upper surface 220u of the second electronic integrated circuit chip 220 and the upper surface 120u of the first electronic integrated circuit chip 120 by using technique, for example, grinding, or planarized until the planarized upper surface 160u of the package body 160 is substantially flush with the upper surface 220u of the second electronic integrated circuit chip 220 and the upper surface 120u of the first electronic integrated circuit chip 120.

As illustrated in FIG. 7C, the structure 200A in FIG. 7B may be disposed on the first surface 110s1 of the carrier plate 110 by using, for example, flip-chip technology. The structure 200A is, for example, a multi-chip heterogeneous integrated module. In addition, although not illustrated, the aforementioned contacts 139 may be pre-formed on the carrier plate 110 or the interposer substrate 140. The carrier plate 110 and the interposer substrate 140 may be butted and electrically connected through the contacts 139.

As illustrated in FIG. 7D, the first underfill 170 may be formed between the interposer substrate 140 and the carrier plate 110 by using, for example, dispensing technology, and encapsulate the contacts 139 (the contacts 139 are illustrated in FIG. 4A) between the interposer substrate 140 and the carrier plate 110.

As illustrated in FIG. 7E, at least one photonic integrated circuit chip 130 may be disposed on the notch 110r of the carrier plate 110 of the structure 200B in FIG. 7D by using, for example, flip-chip technology. The arranged structure is illustrated in FIG. 7F. In an embodiment, the structure 200B in FIG. 7E may be inverted so that the notch 110r faces upward for the photonic integrated circuit chip 130 being disposed downwardly in the notch 110r. Although not illustrated, the aforementioned contacts 137 may be pre-formed on the interposer substrate 140 or the photonic integrated circuit chip 130. The interposer substrate 140 and the photonic integrated circuit chip 130 may be butted and electrically connected through the contacts 137.

Then, the second underfill 180 (illustrated in FIG. 4A) may be formed between the interposer substrate 140 in FIG. 7F and the photonic integrated circuit chip 130 by using, for example, dispensing technology, and encapsulate the contacts 137 (the contacts 137 are illustrated in FIG. 4A) between the interposer substrate 140 and the photonic integrated circuit chip 130.

Then, although not illustrated, in another embodiment, the adhesive may be formed between the photonic integrated circuit chip 130 and the carrier plate 110, by using, for example, dispensing technology, for fixing the relative position between the photonic integrated circuit chip 130 and the carrier plate 110.

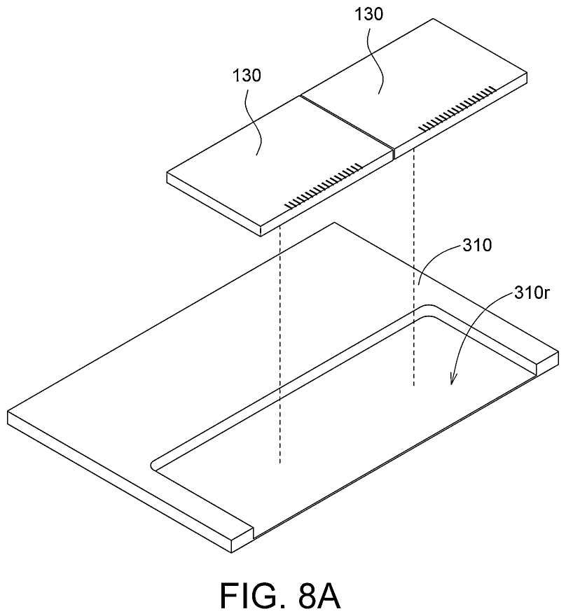

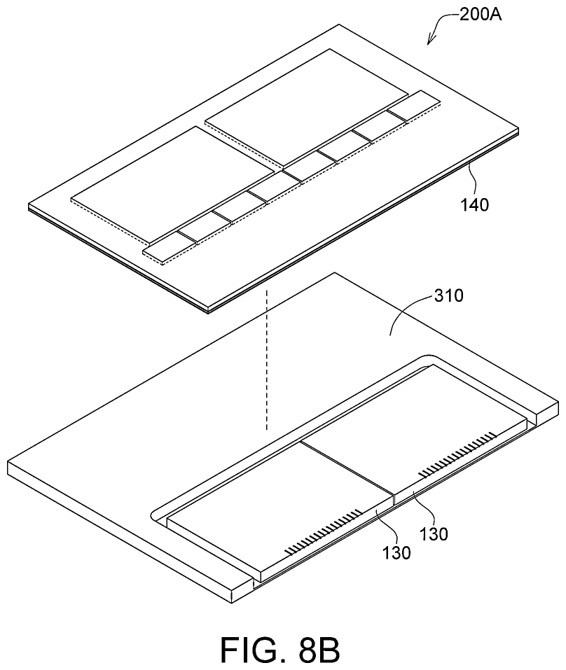

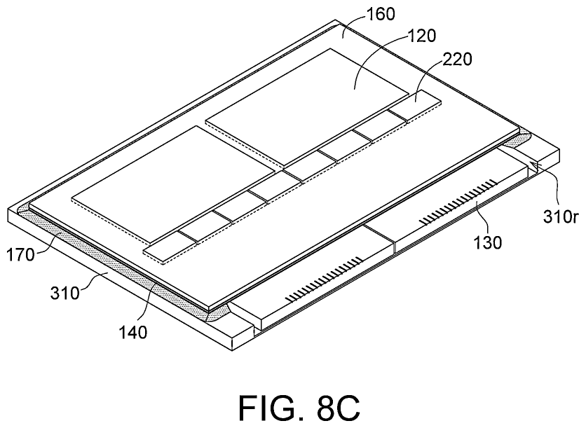

Referring to FIGS. 8A to 8C, FIGS. 8A to 8C illustrate the manufacturing process diagram of the semiconductor package 300 in FIG. 5A.

As illustrated in FIG. 8A, at least one photonic integrated circuit chip 130 is disposed in the notch 310r of the carrier plate 310.

As illustrated in FIG. 8B, although not illustrated, in another embodiment, the adhesive may be formed between the photonic integrated circuit chip 130 and the carrier plate 310, by using, for example, dispensing technology, for fixing the relative position between the photonic integrated circuit chip 130 and the carrier plate 310.

As illustrated in FIG. 8B, the aforementioned structure 200A is disposed on the carrier plate 310. The arranged structure is illustrated in FIG. 8C. Although not illustrated, the aforementioned contacts 139 may be pre-formed on the carrier plate 310 or the interposer substrate 140. The carrier plate 310 and the interposer substrate 140 may be butted and electrically connected through the contacts 139. In addition, although not illustrated, the aforementioned contacts 137 may be pre-formed on the photonic integrated circuit chip 130 or the interposer substrate 140. The photonic integrated circuit chip 130 and the interposer substrate 140 may be butted and electrically connected through the contacts 137.

As illustrated in FIG. 8C, the first underfill 170 may be formed between the interposer substrate 140 and the carrier plate 310 by using, for example, dispensing technology, and encapsulate the contacts 139 between the interposer substrate 140 and the carrier plate 310.

Then, the second underfill 180 (illustrated in FIG. 2A) may be formed between the interposer substrate 140 in FIG. 8C and the photonic integrated circuit chip 130 by using, for example, dispensing technology, and encapsulate the contacts 137 between the interposer substrate 140 and the photonic integrated circuit chip 130.

In summary, the embodiment of the present invention proposes a semiconductor package and a manufacturing method thereof. Due to the photonic integrated circuit chip being manufactured individually, the photonic integrated circuit chip may be prevented from participating in the manufacturing process of the first electronic integrated circuit chip, thereby reducing pollution on components (for example, optical waveguide components) of the photonic integrated circuit chip or the probability of damage. In an embodiment, due to the photonic integrated circuit chip being manufactured individually, it may meet the diverse manufacturing requirements in high-mix low-volume and/or shorten the development time of packaging modules, and other advantages. In another embodiment, the photonic integrated circuit chip may be disposed in the notch of the carrier plate. Due to the design of the notch, the photonic integrated circuit chip is allowed to be assembled into the notch of the carrier plate after being individually manufactured.

It will be apparent to those skilled in the art that various modifications and variations could be made to the disclosed embodiments. It is intended that the specification and examples be considered as exemplary only, with a true scope of the disclosure being indicated by the following claims and their equivalents.

What is claimed is:

1. A semiconductor package, comprising:
a carrier plate having a notch, a first surface and a second surface opposite to the first surface, wherein the notch extends from the first surface toward the second surface;
a photonic integrated circuit chip disposed within the notch;
an electronic integrated circuit chip disposed on the first surface of the carrier plate; and
an interposer substrate disposed on the first surface of the carrier plate;
wherein the photonic integrated circuit chip and the electronic integrated circuit chip are disposed on two opposite surfaces of the interposer substrate respectively.

2. The semiconductor package as claimed in claim 1, wherein the notch extends to the second surface from the first surface; the carrier plate further has a third surface and a fourth surface opposite the third surface, the third surface and the fourth surface extend between the first surface and the second surface, and the notch further extends from the third surface toward the fourth surface.

3. The semiconductor package as claimed in claim 1, wherein the notch does not extend to the second surface.

4. The semiconductor package as claimed in claim 1, wherein the photonic integrated circuit chip is entirely disposed within the notch.

5. The semiconductor package as claimed in claim 1, wherein the photonic integrated circuit chip has a lower surface, and the lower surface of the photonic integrated circuit chip is recessed relative to the second surface.

6. The semiconductor package as claimed in claim 1, further comprising:
a passive component embedded in the interposer substrate.

7. The semiconductor package as claimed in claim 1, further comprising:
a package body encapsulating the electronic integrated circuit chip;
wherein the electronic integrated circuit chip has an upper surface, and the upper surface is exposed from the package body.

8. The semiconductor package as claimed in claim 7, wherein the package body has an upper surface, and the upper surface of the package body is substantially flush with the upper surface of the electronic integrated circuit chip.

9. The semiconductor package as claimed in claim 1, further comprising:
a passive component disposed on the interposer substrate; and
a package body encapsulating the passive component.

10. The semiconductor package as claimed in claim 1, further comprising:
a first underfill formed between the interposer substrate and the carrier plate.

11. The semiconductor package as claimed in claim 1, further comprising:
a second underfill formed between the interposer substrate and the photonic integrated circuit chip.

12. A manufacturing method for a semiconductor package, comprising:
providing a carrier plate, wherein the carrier plate has a notch, a first surface and a second surface opposite to the first surface, and the notch extends from the first surface toward the second surface; and
disposing a photonic integrated circuit chip and an electronic integrated circuit chip on the carrier through an interposer substrate, wherein the photonic integrated circuit chip is disposed within the notch, the electronic integrated circuit chip and the interposer substrate are disposed on the first surface of the carrier plate, and the photonic integrated circuit chip and the electronic integrated circuit chip are disposed on two opposite surfaces of the interposer substrate respectively.

13. The manufacturing method as claimed in claim 12, wherein disposing the photonic integrated circuit chip and the electronic integrated circuit chip on the carrier plate comprises:
disposing the electronic integrated circuit chip on the interposer substrate.

14. The manufacturing method as claimed in claim 13, wherein disposing the photonic integrated circuit chip and the electronic integrated circuit chip on the carrier plate comprises:
forming a package body to encapsulate the electronic integrated circuit chip to form a multi-chip heterogeneous integrated module; and
disposing the multi-chip heterogeneous integrated module on the carrier plate.

15. The manufacturing method as claimed in claim 14, wherein forming the package body to encapsulate the electronic integrated circuit chip comprises:
planarizing the package body until an upper surface of the package body is substantially flush with an upper surface of the electronic integrated circuit chip.

16. The manufacturing method as claimed in claim 12, wherein disposing the photonic integrated circuit chip and the electronic integrated circuit chip on the carrier plate comprises:
forming a first underfill between the interposer substrate and the carrier plate.

17. The manufacturing method as claimed in claim 12, wherein disposing the PIC and the electronic integrated circuit chip on the carrier plate comprises:
forming a second underfill between the interposer substrate and the photonic integrated circuit chip.
